(19) United States
(12) Patent Application Publication
(10) Pub. No.: US 2025/0295036 A1
(43) Pub. Date: Sep. 18, 2025

(54) Flexible Ultrasonic Transducer and Flexible Ultrasonic Transducer Module

(71) Applicant: QISDA CORPORATION, Taoyuan City (TW)

(72) Inventors: Fu-Sheng Jiang, Taoyuan City (TW); Yang-Zong Fan, Taoyuan City (TW)

(73) Assignee: QISDA CORPORATION, Taoyuan City (TW)

(21) Appl. No.: 19/015,538

(22) Filed: Jan. 9, 2025

(30) Foreign Application Priority Data
Mar. 15, 2024 (TW) 113109685

(51) Int. Cl. H10N 30/88; G01N 29/22; G01N 29/24; H10N 39/00

(52) U.S. Cl. CPC H10N 30/883; G01N 29/221; G01N 29/2437; H10N 39/00; G01N 2291/106

(57) ABSTRACT

A flexible ultrasonic transducer is provided, which includes a reflection structure, a transducer array, a backing layer and a matching layer. The reflection structure has a concave-convex structure, and the concave-convex structure includes at least one of one or a plurality of protrusion portions and one or a plurality of recess portions. The transducer array includes a plurality of transducer elements. Each transducer element emits an ultrasonic signal such that the ultrasonic signal is incident upon at least one of the one or the plurality of protrusion portions, or at least one of the one or the plurality of recess portions. The backing layer is disposed on a first side of the transducer array, and the backing layer is between the reflection structure and the transducer array. The matching layer is disposed on a second side of the transducer array.

### BACKGROUND OF THE INVENTION

### 1. Field of the Invention

The present invention relates to a flexible ultrasonic transducer and a flexible ultrasonic transducer module, and more particularly, to a flexible ultrasonic transducer and a flexible ultrasonic transducer module with reflection structure having concave and convex structure.

### 2. Description of the Prior Art

With the rapid development of medical technology, ultrasonic inspection method has become a popular technology for non-invasive measurements. The ultrasonic inspection method is to emit ultrasonic signals to human skin and then detect the reflected signals to determine the shape and position of invisible objects under the skin for various medical purposes. Handheld ultrasonic sensing devices are commonly used in clinical inspection. However, the medical professional operator must manually hold the handheld ultrasonic sensing device to operate and the subject to be measured also needs to keep motionless during scanning. On the other hand, some physiological monitoring projects may require long-term, and qualitative and quantitative measurement for monitoring, such that the handheld ultrasonic sensing device may be unsuitable for such inspection project. In addition, a patch-type ultrasonic sensing device can be attached to the skin surface, and the patch-type ultrasonic sensing device is usually flexible. Since the flexible design may bend or deform according to the shape of different parts of the human body, the patch-type ultrasonic sensing device can be fixedly attached to the skin without manually operation during inspection. As such, the patch-type ultrasonic sensing devices are gradually used in inspection. However, when the patch-type ultrasonic sensing device is attached to the human skin, the position and arrangement of the ultrasonic transducer elements in the patch-type ultrasonic sensing device would change accordingly, so that the spatial information will be confused and the focusing function of the transducer element will be also lost. As a result, the reflected ultrasonic signal cannot be used to restore the correct coordinate system, thereby resulting in distortion of the ultrasonic image. Thus, the prior art has to be improved.

### SUMMARY OF THE INVENTION

It is therefore a primary objective of the present invention to provide a flexible ultrasonic transducer and a flexible ultrasonic transducer module with reflection structure having concave and convex structure, to solve the above-mentioned problem.

According to an embodiment of the present invention, an exemplary flexible ultrasonic transducer is disclosed. The exemplary flexible ultrasonic transducer comprises a reflection structure having a concave-convex structure, the concave-convex structure comprising at least one of one or a plurality of protrusion portions and one or a plurality of recess portions; a transducer array comprising a plurality of transducer elements, wherein each transducer element emits an ultrasonic signal such that the ultrasonic signal is incident upon at least one of the one or the plurality of protrusion portions or at least one of the one or the plurality of recess portions; a backing layer disposed on a first side of the transducer array, and the backing layer being between the reflection structure and the transducer array; and a matching layer disposed on a second side of the transducer array.

According to an embodiment of the present invention, an exemplary flexible ultrasonic transducer module is disclosed. The exemplary flexible ultrasonic transducer module comprises a flexible ultrasonic transducer, comprising: a reflection structure having a concave-convex structure, the concave-convex structure comprising at least one of one or a plurality of protrusion portions and one or a plurality of recess portions; a transducer array comprising a plurality of transducer elements, wherein each transducer element emits an ultrasonic signal such that the ultrasonic signal is incident upon at least one of the one or the plurality of protrusion portions or at least one of the one or the plurality of recess portions; a backing layer disposed on a first side of the transducer array, and the backing layer being between the reflection structure and the transducer array; and an adhesive layer disposed on a second side of the transducer array, wherein the flexible ultrasonic transducer module is adhered to an object via the adhesive layer; and an ultrasonic system coupled to each transducer element for transmitting reflected ultrasonic signals received by each transducer element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a flexible ultrasonic transducer module according to an embodiment of the present invention.

FIG. 2 is a schematic diagram illustrating the reflection structure and the transducer array shown in FIG. 1 according to an embodiment of the present invention.

FIG. 3 is a schematic diagram illustrating the transducer array while receiving reflected ultrasonic waves from different areas according to an embodiment of the present invention.

FIG. 4 is a schematic diagram illustrating a process of arranging the transducer array on the substrate according to an embodiment of the present invention.

FIG. 5 is a schematic diagram illustrating a process of arranging the reflection structure on the substrate according to an embodiment of the present invention.

FIG. 6 is a schematic diagram illustrating a process of arranging the transducer array on a substrate according to an alternative embodiment of the present invention.

FIG. 7 is a schematic diagram illustrating a process of cutting the surface of the substrate to form a concave-convex structure according to an embodiment of the present invention.

FIG. 8 and FIG. 9 are schematic diagrams illustrating various processes of arranging an encapsulation layer according to embodiments of the present invention.

### DETAILED DESCRIPTION

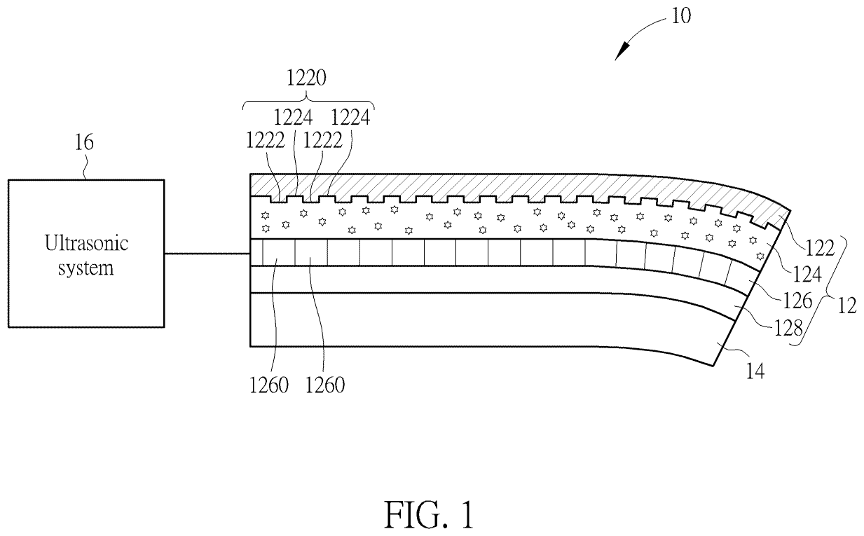

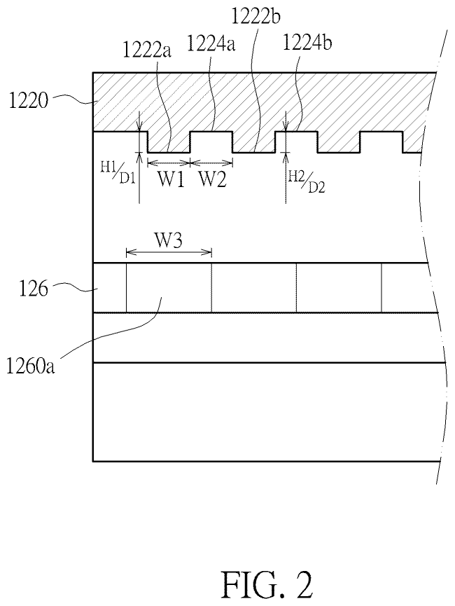

Please refer to FIG. 1, which is a schematic diagram illustrating a cross-sectional view of a flexible ultrasonic transducer module 10 according to an embodiment of the present invention. The flexible ultrasonic transducer module 10 includes a flexible ultrasonic transducer 12. The flexible ultrasonic transducer 12 includes a reflection structure 122, a backing layer 124, a transducer array 126 and a matching layer 128. The reflection structure 122 may reflect ultrasonic signals. The reflection structure 122 includes a concave-convex structure 1220. The concave-convex structure 1220 includes at least one protrusion portion 1222 and/or at least one recess portion. For example, as shown in FIG. 1, the concave-convex structure 1220 includes a plurality of protrusion portions 1222 and a plurality of recess portions 1224. When the concave-convex structure includes the plurality of protrusion portions, the plurality of protrusion portions may have the same or different heights. For example, as shown in FIG. 2, the concave-convex structure 1220 includes protrusion portions 1222a, 1222b. The protrusion portion 1222a has a height H1. The protrusion portion 1222b has a height H2. The height H1 of the protrusion portion 1222a may be the same as the height H2 of the protrusion portion 1222b. In another embodiment, the height H1 of the protrusion portion 1222a may be different from the height H2 of the protrusion portion 1222b. When the concave-convex structure includes the plurality of recess portions, the plurality of recess portions may have the same or different depths. For example, as shown in FIG. 2, the concave-convex structure 1220 includes recess portions 1224a, 1224b. The recess portion 1224a has a depth D1. The recess portion 1224b has a depth D2. The depth D1 of the recess portion 1224a may be the same as the depth D2 of the recess portion 1224b. In another embodiment, the depth D1 of the recess portion 1224a may be different from the depth D2 of the recess portion 1224b.

When the flexible ultrasonic transducer 12 is a two-dimensional array, the concave-convex structure 1220 of the reflection structure 122 may be arranged in a two-dimensional manner. For example, when the concave-convex structure includes a plurality of protrusion portions and a plurality of recess portions, the plurality of protrusion portions are arranged along a first direction. The plurality of recess portions are arranged along a second direction. The first direction may be the same as or different from the second direction. The plurality of protrusion portions includes a first protrusion portion having a first height and a second protrusion portion having a second height. The plurality of recess portions includes a first recess portion having a first depth and a second recess portion having a second depth. The first height of the first protrusion portion may be the same as or different from the second height of the second protrusion portion. The first depth of the first recess portion may be the same as or different from the second depth of the second recess portion.

The transducer array 126 includes a plurality of transducer elements 1260. The transducer element 1260 is utilized for emitting and receiving ultrasonic signals. For example, the transducer element 1260 may be a micro-machined ultrasonic transducer (MUT) or a piezoelectric ultrasonic transducer, but not limited thereto. Each transducer element 1260 may emit the ultrasonic signal, and the ultrasonic signal is incident upon at least one of the protrusion portions 1222. Each transducer element 1260 may emit the ultrasonic signal, and the ultrasonic signal is incident upon at least one of the recess portions 1224. The width of each transducer element 1260 may be greater than the width of the protrusion portion of the concave-convex structure 1220. As shown in FIG. 2, the protrusion portion 1222a has a width W1, and the transducer element 1260 has a width W3. The width W3 of the transducer element 1260 is greater than the width W1 of the protrusion portion 1222a. The width of each transducer element 1260 may be greater than the width of the recess portion of the concave-convex structure 1220. As shown in FIG. 2, the recess portion 1224a has a width W2, and the transducer element 1260 has a width W3. The width W3 of the transducer element 1260 is greater than the width W2 of the recess portion 1224a.

Please further refer to FIG. 1. The backing layer 124 is disposed between the reflection structure 122 and the transducer array 126. The backing layer 124 may cover the surface of the concave-convex structure 1220. The backing layer 124 may be made of a material with high ultrasonic wave attenuation. The backing layer 124 may be porous foam material, polyurethane resin (PU), epoxy resin, epoxy resin with powder, or a combination thereof. As shown in FIG. 1, the backing layer 124 is disposed on one side of the transducer array 126, and the matching layer 128 is disposed on the other side of the transducer array 126. The flexible ultrasonic transducer 10 further includes an adhesive layer 14. The matching layer 128 is disposed between the adhesive layer 14 and the transducer array 126. The flexible ultrasonic transducer module 10 may be adhered to an object (object or human body under test) via the adhesive layer 14. For example, the flexible ultrasonic transducer module 10 may be adhered to the human skin via the adhesive layer 14. A matching layer acoustic impedance of the matching layer 128 may be between a transducer acoustic impedance of the transducer array 126 and an adhesive layer acoustic impedance of the adhesive layer 14. In addition, the adhesive layer 14 can not only be utilized for adhesion, but also be utilized as the matching layer. For example, the adhesive layer 14 may include a matching layer 128 disposed on one side of the adhesive layer 14 adjacent to the transducer array 126. The flexible ultrasonic transducer module 10 further includes an ultrasonic system 16. The ultrasonic system 16 is wired or wirelessly coupled to the transducer array 126. The ultrasonic system 16 may communicate with the transducer array 126 through a wired or wireless connection to obtain the reflected ultrasonic signal that is received by each transducer element 1260 from the transducer array 126. Furthermore, the ultrasound system 16 may transmit the reflected ultrasound signal to external devices. The ultrasonic system 16 may transmit the reflected ultrasonic signals received by each transducer element 1260 to the external device via wireless connections for subsequent operation.

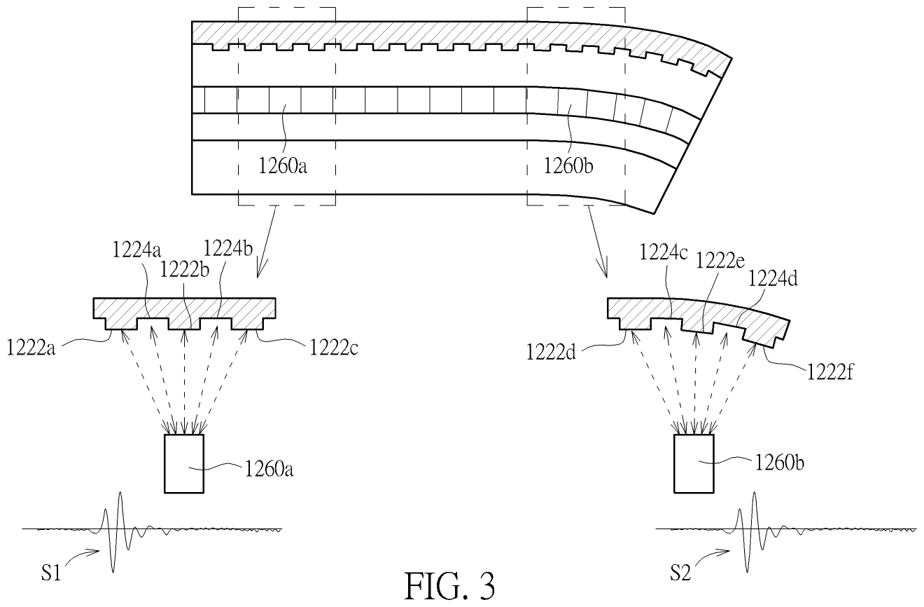

Each transducer element 1260 may emit ultrasonic signals to the protrusion portions 1222 and the recess portions 1224 of the concave-convex structure 1220, and receive reflected ultrasonic signals reflected by the protrusion portions 1222 and the recess portions 1224. Each transducer array element 1260 may emit the ultrasonic signals toward the reflection structure 1220, such that the ultrasonic signals may be incident upon one or more protrusion portions 1222 and/or one or more recess portions 1224. The transducer element 1260 may receive the reflected ultrasonic signals reflected from at least one of the one or more protrusion portions 1222 or from at least one of the one or more recess portions 1224. For example, please refer to FIG. 3. FIG. 3 is a schematic diagram illustrating the transducer array while receiving reflected ultrasonic waves from different areas according to an embodiment of the present invention. The flexible ultrasonic transducer module 10 is flexible. When the flexible ultrasonic transducer module 10 is attached to the human skin or object, the degree of the deflection of the flexible ultrasonic transducer module 10 may vary based on the appearance of the attached object. When the transducer element 1260 emits the ultrasonic signals to the protrusion portions 1222 and the recess portions 1224 of the concave-convex structure 1220, the reflected ultrasonic signals reflected by the protrusion portions 1222 and the recess portions 1224 may be utilized for determining the degree of the deflection of the flexible ultrasonic transducer module 10. As shown in FIG. 3, the transducer element 1260a emits the ultrasonic signal to the protrusion portions 1222a, 1222b, 1222c and the recess portions 1224a, 1224b of the concave-convex structure 1220, and receives the reflected ultrasonic signal S1 reflected by the protrusion portions 1222a, 1222b, 1222c and the recess portions 1224a and 1224b. Since the smaller the width of the transducer element is, the lager the divergence angle is, the ultrasonic signal emitted by the transducer element may cover more protrusion portions 1222 and/or recess portions 1224. The transducer element 1260b emits the ultrasonic signal to the protrusion portions 1222d, 1222e, 1222f and the recess portions 1224c, 1224d of the concave-convex structure 1220, and receives the reflected ultrasonic signal reflected by the protrusion portions 1222d, 1222e, 1222f and the recess portions 1224c, 1224d. Since the flexible ultrasonic transducer module 10 has a concave-convex structure 1220, the reflected ultrasonic signal reflected by the flat area of the concave-convex structure 1220 may be different from the reflected ultrasonic signal reflected by the deflection area of the concave-convex structure 1220. For example, as shown in FIG. 3, the degree of deflection of the area corresponding to the protrusion portions 1222a, 1222b, 1222c and the recess portions 1224a, 1224 is different from the degree of deflection of the area corresponding to the protrusion portions 1222d, 1222e, 1222f and the recess portions 1224c, 1224d. The reflected ultrasonic signal S1 is different from the reflected ultrasonic signal S2. Therefore, the transducer element 1260 may emit ultrasonic signals to the concave-convex structure 1220, receive the reflected ultrasonic signals reflected by the protrusion portions and the recess portions, and accordingly determine the deflection situation of the flexible ultrasonic transducer module 10 accordingly, such that the coordinate system of the ultrasonic imaging device may be corrected according to the deflection situation of the flexible ultrasonic transducer module 10, thus preventing distortion of the ultrasonic image and obtaining high-quality ultrasonic images.

On the other hand, each transducer element 1260 may also emit ultrasonic signals toward the matching layer 128 and the adhesive layer 14, and receive reflected ultrasonic signals from the matching layer 128 and the adhesive layer 14. When the transducer element 1260 emits the ultrasonic signal toward the matching layer 128 and the adhesive layer 14, the ultrasonic signal is incident upon the object to be measured, and the object to be measured reflects the ultrasonic signal to form a reflected ultrasonic signal. The reflected ultrasonic signal passes through the matching layer 128 and adhesive layer 14 and is transmitted to the transducer array element 1260.

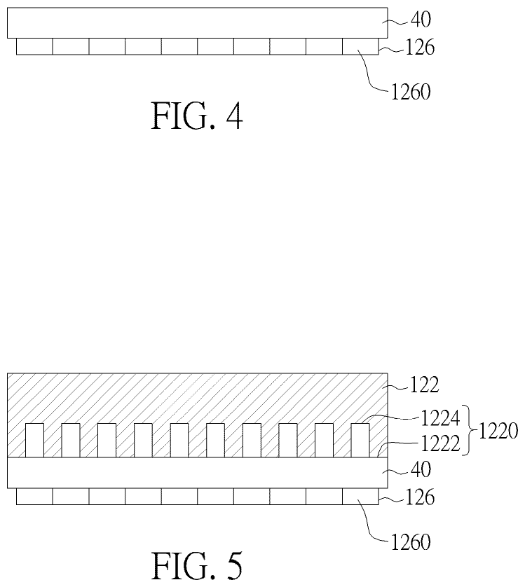

For ultrasonic transducers of a micro-electro-mechanical system (MEMS) structure, a substrate is utilized to carry and fix the ultrasonic transducers. For example, the transducer element 1260 of the transducer array 126 is a micro-machined ultrasonic transducer, and the transducer element 1260 of the transducer array 126 may be manufactured by using micro-electro-mechanical process technology. The transducer element 1260 may be disposed on a substrate during micro-electro-mechanical manufacturing process. For example, the substrate may be a glass substrate, a silicon substrate, or a plastic substrate, but not limited thereto. In an embodiment, regarding the manufacturing method of the reflection structure 122 and the transducer array 126 of the flexible ultrasonic transducer 12, please refer to FIG. 4 and FIG. 5. FIG. 4 is a schematic diagram illustrating a process of arranging the transducer array 126 on a substrate 40 according to an embodiment of the present invention. FIG. 5 is a schematic diagram illustrating a process of arranging the reflection structure 122 on the substrate 40 according to an embodiment of the present invention. As shown in FIG. 4, a substrate 40 is provided. The substrate 40 may be a plastic substrate. The transducer elements 1260 of the transducer array 126 are arranged on one side of the substrate 40. As shown in FIG. 5, the reflection structure 122 is bonded to the other side of the substrate 40 by using a bonding method. The reflection structure 122 is a concave-convex reflective plate. The reflection structure 122 includes a concave-convex structure 1220, and the concave-convex structure 1220 includes a plurality of protrusion portions 1222 and a plurality of recess portions 1224. The substrate 40 may be utilized for acting as the adhesive layer 124. The ultrasonic signal emitted by the transducer element 1260 may pass through the substrate 40 and emit to the protrusion portion 1222 and/or the recess portion 1224 of the concave-convex structure 1220. Then, the transducer element 1260 receives the reflected ultrasonic signal reflected by the protrusion portion 1222 and/or the recess portion 1224 of the concave-convex structure 1220.

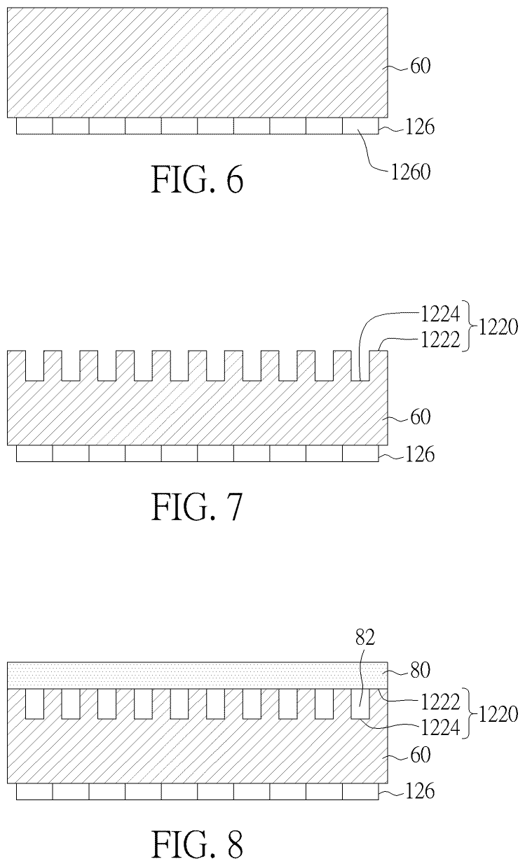

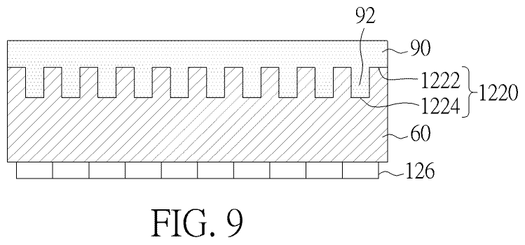

In an alternative embodiment, regarding the manufacturing method of the reflection structure 122 and the transducer array 126 of the flexible ultrasonic transducer 12, please refer to FIG. 6 to FIG. 8. FIG. 6 is a schematic diagram illustrating a process of arranging the transducer array 126 on a substrate 60 according to an alternative embodiment of the present invention. FIG. 7 is a schematic diagram illustrating a process of cutting the surface of the substrate 60 to form a concave-convex structure according to an embodiment of the present invention. FIG. 8 is a schematic diagram illustrating a process of arranging an encapsulation layer 80 according to an embodiment of the present invention. As shown in FIG. 6, a substrate 60 is provided. The substrate 60 may be a glass substrate or a silicon substrate. The transducer elements 1260 of the transducer array 126 are arranged on one side of the substrate 60. The surface of the substrate 60 is cut by using a dicing method to form a plurality of recess portions of the concave-convex structure. As shown in FIG. 7, the cut-off portions of the substrate 60 are the recess portions 1224 of the concave-convex structure 1220. The recess portion 1224 is formed between two protrusion portions 1222. The protrusion portions 1222 and the recess portions 1224 are alternately arranged along the surface of the substrate 60. The concave-convex structure 1220 with the protrusion portions 1222 and the recess portions 1224 formed on the substrate 60 may be utilized as the reflection structure of the ultrasonic transducer, and other portions of the substrate 60 may be utilized as the backing layer of the ultrasonic transducer. Further, as shown in FIG. 8, one side surface of the substrate 60 having the concave-convex structure 1220 is packaged by using a flat mounting method to form an encapsulation layer 80. Air exists in pore 82 formed between the encapsulation layer 80 and the recess portions 1224. The ultrasonic signal emitted by the transducer element 1260 may pass through the substrate 60 and emit to the encapsulation layer 80 or the pore 82. The substrate 60, the packaging layer 80 and the air have different acoustic impedances, thus reflected ultrasonic signals are generated in different media. In an alternative embodiment, after cutting the surface of the substrate 60 to form the concave-convex structure, the side surface of the substrate 60 having the concave-convex structure 1220 may be packaged by using a sealing method to form an encapsulation layer 90. As shown in FIG. 9, the encapsulation layer 90 is on the surface of the concave-convex structure 1220 and fills the pores 92 in the concave-convex structure 1220. In other words, the pores between the encapsulation layer and the concave-convex structure may be filled or retained.

In summary, the flexible ultrasonic transducer of the embodiments of the present invention includes the reflection structure with concave-convex structure. When the transducer element 1260 emits the ultrasonic signal to the concave-convex structure 1220 and receives the reflected ultrasonic signal reflected by the protrusion portion 1222 and the recess portion 1224. The reflected ultrasonic signal may be utilized for determining the degree of deflection of the flexible ultrasonic transducer module 10, and then the coordinate system of the ultrasonic imaging device may be corrected according to the degree of deflection of the flexible ultrasonic transducer module 10, thereby preventing distortion of the ultrasonic image for high-quality ultrasonic image.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flexible ultrasonic transducer, comprising:
a reflection structure having a concave-convex structure, the concave-convex structure comprising at least one of one or a plurality of protrusion portions and one or a plurality of recess portions;
a transducer array comprising a plurality of transducer elements, wherein each transducer element emits an ultrasonic signal such that the ultrasonic signal is incident upon at least one of the one or the plurality of protrusion portions or at least one of the one or the plurality of recess portions;
a backing layer disposed on a first side of the transducer array, and the backing layer being between the reflection structure and the transducer array; and
a matching layer disposed on a second side of the transducer array.

2. The flexible ultrasonic transducer of claim 1, wherein when the concave-convex structure comprises the plurality of protrusion portions, the plurality of protrusion portions comprises a first protrusion portion and a second protrusion portion, and a first height of the first protrusion portion is the same as or different from a second height of the second protrusion portion.

3. The flexible ultrasonic transducer of claim 1, wherein when the concave-convex structure comprises the plurality of recess portions, the plurality of recess portions comprises a first recess portion and a second recess portion, and a first depth of the first recess portion is the same as or different from a second depth of the second recess portion.

4. The flexible ultrasonic transducer of claim 1, wherein when the concave-convex structure comprises the plurality of protrusion portions and the plurality of recess portions, the plurality of protrusion portions comprises a first protrusion portion and a second protrusion portion, and a first height of the first protrusion portion is the same as or different from a second height of the second protrusion portion, the plurality of recess portions comprises a first recess portion and a second recess portion, and a first depth of the first recess portion is the same as or different from a second depth of the second recess portion, wherein the plurality of protrusion portions are arranged along a first direction, and the plurality of recess portions are arranged along a second direction, and the first direction is the same as or different from the second direction.

5. The flexible ultrasonic transducer of claim 1, wherein the one or the plurality of recess portions comprises a first recess portion, wherein a width of each transducer element is greater than a width of the first recess portion.

6. The flexible ultrasonic transducer of claim 1, wherein the one or the plurality of protrusion portions comprises a first protrusion portion, wherein a width of each transducer element is greater than a width of the first protrusion portion.

7. The flexible ultrasonic transducer of claim 1, wherein each transducer element emits a first ultrasonic signal toward the reflection structure and receives a first reflected ultrasonic signal reflected from at least one of the one or the plurality of protrusion portions or the one or the plurality of recess portions.

8. The flexible ultrasonic transducer of claim 7, wherein each transducer element emits a second ultrasonic signal toward the matching layer and receives a second reflected ultrasonic signal reflected from the matching layer.

9. The flexible ultrasonic transducer of claim 1, wherein each transducer element comprises a piezoelectric ultrasonic transducer or a micro-machined ultrasonic transducer.

10. The flexible ultrasonic transducer of claim 1, wherein a material of the backing layer comprises epoxy resin, polyurethane or a combination thereof.

11. A flexible ultrasonic transducer module, comprising:
a flexible ultrasonic transducer, comprising:
a reflection structure having a concave-convex structure, the concave-convex structure comprising at least one of one or a plurality of protrusion portions and one or a plurality of recess portions;
a transducer array comprising a plurality of transducer elements, wherein each transducer element emits an ultrasonic signal such that the ultrasonic signal is incident upon at least one of the one or the plurality of protrusion portions or at least one of the one or the plurality of recess portions;
a backing layer disposed on a first side of the transducer array, and the backing layer being between the reflection structure and the transducer array; and
an adhesive layer disposed on a second side of the transducer array, wherein the flexible ultrasonic transducer module is adhered to an object via the adhesive layer; and
an ultrasonic system coupled to each transducer element for transmitting reflected ultrasonic signals received by each transducer element.

12. The flexible ultrasonic transducer module of claim 11, wherein the adhesive layer comprises a matching layer disposed on a side of the adhesive layer adjacent to the transducer array, wherein a matching layer acoustic impedance of the matching layer is between a transducer acoustic impedance of the transducer array and an adhesive layer acoustic impedance of the adhesive layer.

13. The flexible ultrasonic transducer module of claim 11, wherein when the concave-convex structure comprises the plurality of protrusion portions, the plurality of protrusion portions comprises a first protrusion portion and a second protrusion portion, and a first height of the first protrusion portion is the same as or different from a second height of the second protrusion portion.

14. The flexible ultrasonic transducer module of claim 11, wherein when the concave-convex structure comprises the plurality of recess portions, the plurality of recess portions comprises a first recess portion and a second recess portion, and a first depth of the first recess portion is the same as or different from a second depth of the second recess portion.

15. The flexible ultrasonic transducer module of claim 11, wherein when the concave-convex structure comprises the plurality of protrusion portions and the plurality of recess portions, the plurality of protrusion portions comprises a first protrusion portion and a second protrusion portion, and a first height of the first protrusion portion is the same as or different from a second height of the second protrusion portion, the plurality of recess portions comprises a first recess portion and a second recess portion, and a first depth of the first recess portion is the same as or different from a second depth of the second recess portion, wherein the plurality of protrusion portions are arranged along a first direction, and the plurality of recess portions are arranged along a second direction, and the first direction is the same as or different from the second direction.

16. The flexible ultrasonic transducer module of claim 11, wherein the one or the plurality of recess portions comprises a first recess portion, wherein a width of each transducer element is greater than a width of the first recess portion.

17. The flexible ultrasonic transducer module of claim 11, wherein the one or the plurality of protrusion portions comprises a first protrusion portion, wherein a width of each transducer element is greater than a width of the first protrusion portion.

18. The flexible ultrasonic transducer module of claim 11, wherein each transducer element emits a first ultrasonic signal toward the reflection structure and emits a second ultrasonic signal toward the adhesive layer, the transducer element receives a first reflected ultrasonic signal reflected from at least one of the one or the plurality of protrusion portions or the one or the plurality of recess portions, and the transducer element receives a second reflected ultrasonic signal reflected from the adhesive layer.

19. The flexible ultrasonic transducer module of claim 11, wherein each transducer element comprises a piezoelectric ultrasonic transducer or a micro-machined ultrasonic transducer.

20. The flexible ultrasonic transducer module of claim 11, wherein a material of the backing layer comprises epoxy resin, polyurethane or a combination thereof.
